(19) United States
(12) Patent Application Publication
(10) Pub. No.: US 2023/0146815 A1
(43) Pub. Date: May 11, 2023

(54) WAFER PLACEMENT TABLE

(71) Applicant: NGK Insulators, Ltd., Nagoya-City (JP)

(72) Inventors: Seiya INOUE, Handa-City (JP); Tatsuya KUNO, Nagoya-City (JP); Ikuhisa MORIOKA, Handa-City (JP)

(73) Assignee: NGK Insulators, Ltd., Nagoya-City (JP)

(21) Appl. No.: 17/819,663

(22) Filed: Aug. 15, 2022

(30) Foreign Application Priority Data
Nov. 10, 2021 (JP) 2021-183241

(51) Int. Cl. H01L 21/687; H01L 21/67

(52) U.S. Cl. CPC H01L 21/68714; H01L 21/67109

(57) ABSTRACT

A wafer placement table includes a ceramic base having a wafer placement surface on its top surface where a wafer is able to be placed and incorporating an electrode; a cooling base having a refrigerant flow channel; and a bonding layer that bonds the ceramic base with the cooling base, wherein in an area that overlaps the wafer placement surface in plan view of the refrigerant flow channel, a cross-sectional area of the refrigerant flow channel at a most downstream part of the refrigerant flow channel is less than the cross-sectional area at a most upstream part of the refrigerant flow channel.

### BACKGROUND OF THE INVENTION

### 1. Field of the Invention

The present invention relates to a wafer placement table.

### 2. Description of the Related Art

Hitherto, there is known a wafer placement table that includes a ceramic base having a wafer placement surface and incorporating an electrode, a cooling base having a refrigerant flow channel, and a bonding layer bonding the ceramic base with the cooling base. For example, Patent Literatures 1 and 2 describe that, in such a wafer placement table, the cooling base made of a metal matrix composite material of which the coefficient of linear thermal expansion is substantially the same as that of the ceramic base is used. Patent Literatures 1 and 2 also describe that the wafer placement table has a terminal hole for allowing insertion of a power supply terminal for supplying electric power to an electrode, gas holes for supplying He gas to the back surface of a wafer, and lift pin holes for allowing insertion of lift pins to lift a wafer from the wafer placement surface.

### CITATION LIST

### Patent Literature

PTL 1: JP 5666748 B

PTL 2: JP 5666749 B

### SUMMARY OF THE INVENTION

However, refrigerant increases in temperature from an inlet toward an outlet, but the cross-sectional shape of the refrigerant flow channel is constant from the inlet of the refrigerant flow channel to the outlet of the refrigerant flow channel, so the wafer tends to be easy to cool down near the inlet of the refrigerant flow channel and hard to cool down near the outlet. As a result, the soaking performance of a wafer is not able to be sufficiently obtained.

The present invention is made to solve such an inconvenience, and it is a main object to increase the soaking performance of a wafer.

A wafer placement table of the present invention includes a ceramic base having a wafer placement surface on its top surface where a wafer is able to be placed and incorporating an electrode, a cooling base having a refrigerant flow channel, and a bonding layer that bonds the ceramic base with the cooling base. In an area that overlaps the wafer placement surface in plan view of the refrigerant flow channel, a cross-sectional area of the refrigerant flow channel at a most downstream part of the refrigerant flow channel is less than the cross-sectional area at a most upstream part of the refrigerant flow channel.

In the wafer placement table, in an area that overlaps the wafer placement surface in plan view of the refrigerant flow channel, a cross-sectional area of the refrigerant flow channel at a most downstream part of the refrigerant flow channel is less than the cross-sectional area at the most upstream part of the refrigerant flow channel. When the wafer placement table is used, refrigerant flows from the most upstream part of the refrigerant flow channel toward the most downstream part while dissipating heat from a high-temperature wafer, so the temperature of refrigerant flowing through the refrigerant flow channel at the most downstream part is higher than the temperature of refrigerant flowing through the refrigerant flow channel at the most upstream part. On the other hand, since the cross-sectional area of the refrigerant flow channel at the most downstream part of the refrigerant flow channel is less than the cross-sectional area of the refrigerant flow channel at the most upstream part of the refrigerant flow channel, a pressure loss is larger at the most downstream part than at the most upstream part, so heat exchange between refrigerant and the wafer is more promoted at the most downstream part than at the most upstream part. Therefore, generally, it is possible to reduce the temperature difference between a location facing the most upstream part of the refrigerant flow channel and a location facing the most downstream part of the refrigerant flow channel in the wafer placement surface. Therefore, the soaking performance of a wafer increases.

In the wafer placement table of the present invention, a cross-sectional area of the refrigerant flow channel may reduce from the most upstream part of the refrigerant flow channel toward the most downstream part of the refrigerant flow channel. With this configuration, the soaking performance of a wafer further increases.

In the wafer placement table of the present invention, a cross-sectional area of the refrigerant flow channel may be adjusted by at least one of fins provided in the refrigerant flow channel, the thickness of each fin, or the length of each fin.

In the wafer placement table of the present invention, a cross-sectional area of the refrigerant flow channel at the most downstream part may be 60% to 90% of a cross-sectional area of the refrigerant flow channel at the most upstream part. When the percentage is lower than or equal to 90%, the soaking performance of a wafer W sufficiently increases. When the percentage is higher than or equal to 60%, refrigerant is able to flow at a sufficient flow rate without an excessively large pressure loss.

In the wafer placement table of the present invention, the cooling base may be made of a metal matrix composite material, and the bonding layer may be a metal bonding layer. With the structure that the cooling base is a metal matrix composite material and the bonding layer is a metal bonding layer, thermal resistance from the refrigerant flow channel to the wafer placement surface is small, so the wafer temperature is susceptible to the influence of the temperature gradient of refrigerant. Therefore, the significance to apply the present invention is high. Since the metal bonding layer has a high thermal conductivity, the metal bonding layer is suitable for heat dissipation. Furthermore, a difference in coefficient of thermal expansion between the ceramic base and the cooling base made of a metal matrix composite material is able to be reduced, so a trouble is less likely to occur even when the stress relaxation properties of the metal bonding layer are low.

The wafer placement table of the present invention may further include a hole extending through the cooling base in an up and down direction. In the refrigerant flow channel, a cross-sectional area of the refrigerant flow channel in an area around the hole may be less than a cross-sectional area of the refrigerant flow channel in an area outside the area around the hole. Generally, an area around just above such a hole in a wafer tends to be a hot spot; however, a cross-sectional area of the refrigerant flow channel in an area around the hole is less than a cross-sectional area of the refrigerant flow channel in an area outside the area around the hole. Therefore, heat dissipation of the area around the hole is promoted. As a result, the soaking performance of a wafer further increases.

### BRIEF DESCRIPTION OF THE DRAWINGS

FIG. 1 is a vertical cross-section view of a wafer placement table 10 placed in a chamber 94.

FIG. 2 is a sectional view of a cooling base 30 when a cross section taken along a horizontal plane passing through a refrigerant flow channel 32 is viewed from above.

FIGS. 3A to 3G are manufacturing process charts of the wafer placement table 10.

FIG. 4 is a sectional view of the cooling base 30 when a cross section taken along a horizontal plane passing through a refrigerant flow channel 82 is viewed from above.

FIG. 5 is a vertical cross-section view of an example in which a part 32x with a narrow width w is provided in the middle of the refrigerant flow channel 32.

FIG. 6 is a vertical cross-section view of an example using a ceramic base 20 without an FR placement surface.

FIG. 7 is a vertical cross-section view of a wafer placement table that includes a refrigerant flow channel 232.

FIG. 8 is a vertical cross-section view of a wafer placement table that includes a refrigerant flow channel 332.

### DETAILED DESCRIPTION OF THE INVENTION

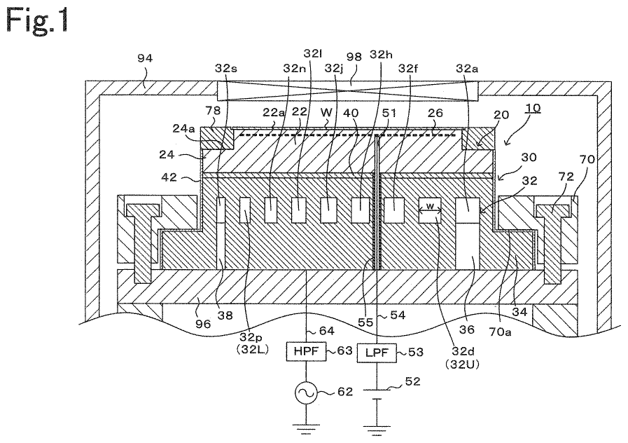

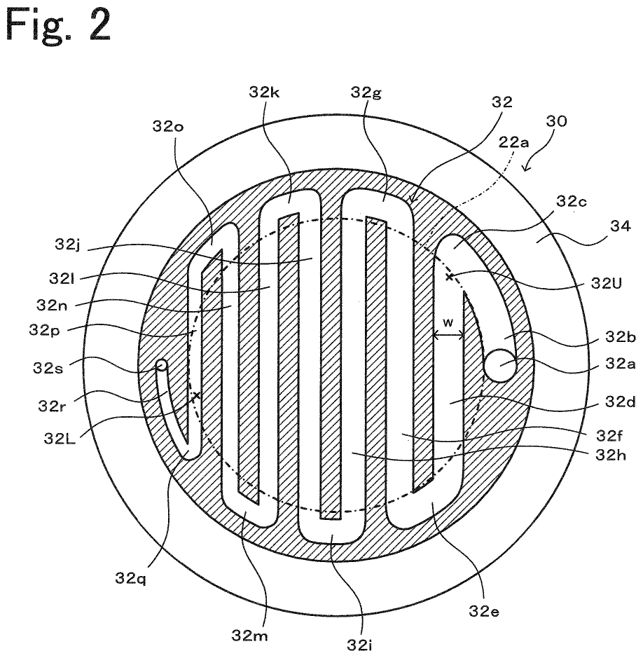

A preferred embodiment of the present invention will be described below with reference to the drawings. FIG. 1 is a vertical cross-section view of a wafer placement table 10 (a sectional view taken along a plane including the central axis of the wafer placement table 10) placed in a chamber 94, and FIG. 2 is a sectional view of a cooling base 30 when a cross section taken along a horizontal plane passing through a refrigerant flow channel 32 is viewed from above. In FIG. 2, a terminal hole 51, a power supply terminal 54, an electrically insulating tube 55, and the like are omitted.

The wafer placement table 10 is used to perform CVD, etching, or the like on a wafer W by using plasma, and is fixed to a mounting plate 96 provided inside a semiconductor process chamber 94. The wafer placement table 10 includes a ceramic base 20, a cooling base 30, and a metal bonding layer 40.

The ceramic base 20 includes an outer peripheral part 24 having an annular focus ring placement surface 24a, on the outer peripheral side of a central part 22 having a circular wafer placement surface 22a. Hereinafter, a focus ring may be abbreviated as “FR”. A wafer W is placed on the wafer placement surface 22a, and a focus ring 78 is placed on the FR placement surface 24a. The ceramic base 20 is made of a ceramic material, typically, alumina, aluminum nitride, or the like. The FR placement surface 24a is lower in level than the wafer placement surface 22a.

The central part 22 of the ceramic base 20 incorporates a wafer attraction electrode 26 on the side close to the wafer placement surface 22a. The wafer attraction electrode 26 is made of a material that contains, for example, W, Mo, WC, MoC, or the like. The wafer attraction electrode 26 is a disk-shaped or mesh-shaped single-pole electrostatic attraction electrode. A layer of the ceramic base 20 on the upper side of the wafer attraction electrode 26 functions as a dielectric layer. A wafer attraction direct current power supply 52 is connected to the wafer attraction electrode 26 via a power supply terminal 54. The power supply terminal 54 is inserted through a terminal hole 51 provided between the bottom surface of the wafer attraction electrode 26 and the bottom surface of the cooling base 30 in the wafer placement table 10. The power supply terminal 54 is provided so as to pass through an electrically insulating tube 55 disposed in a through-hole extending through the cooling base 30 and the metal bonding layer 40 in the up and down direction in the terminal hole 51 and reach the wafer attraction electrode 26 from the bottom surface of the ceramic base 20. A low pass filter (LPF) 53 is provided between the wafer attraction direct current power supply 52 and the wafer attraction electrode 26.

The cooling base 30 is a disk member made of a metal matrix composite material (also referred to as metal matrix composite (MMC)). The cooling base 30 has the refrigerant flow channel 32 in which refrigerant is able to circulate. The refrigerant flow channel 32 is connected to a refrigerant supply passage 36 and a refrigerant discharge passage 38, and refrigerant discharged from the refrigerant discharge passage 38 is adjusted in temperature and then returned to the refrigerant supply passage 36 again. Examples of the MMC include a material including Si, SiC, and Ti, and a material obtained by impregnating an SiC porous body with Al and/or Si. The material including Si, SiC, and Ti is referred to as SiSiCTi, the material that impregnates an SiC porous body with Al is referred to as AlSiC, and the material that impregnates an SiC porous body with Si is referred to as SiSiC. When the ceramic base 20 is an alumina base, the MMC used for the cooling base 30 is preferably AlSiC, SiSiCTi, or the like of which the coefficient of thermal expansion is close to the coefficient of thermal expansion of alumina. The cooling base 30 is connected to an RF power supply 62 via a power supply terminal 64. A high pass filter (HPF) 63 is disposed between the cooling base 30 and the RF power supply 62. The cooling base 30 has a flange 34 on the bottom surface side. The flange 34 is used to clamp the wafer placement table 10 to a mounting plate 96.

As shown in FIG. 2, the refrigerant flow channel 32 is formed in a one-stroke pattern from an inlet 32a to an outlet 32s over the entire area other than the flange 34 in the cooling base 30 when the cross section of the refrigerant flow channel 32, taken along the horizontal plane, is viewed from above. In the present embodiment, the refrigerant flow channel 32 is formed in a zigzag shape. Specifically, the refrigerant flow channel 32 is formed in a zigzag shape so as to run from the inlet 32a connected to the refrigerant supply passage 36 via a circular arc part 32b, a folded part 32c, a straight part 32d, a folded part 32e, a straight part 32f, a folded part 32g, a straight part 32h, a folded part 32i, a straight part 32j, a folded part 32k, a straight part 32l, a folded part 32m, a straight part 32n, a folded part 32o, a straight part 32p, a folded part 32q, and a circular arc part 32r to the outlet 32s connected to the refrigerant discharge passage 38. Here, when a most upstream part 32U and a most downstream part 32L are determined in an area that overlaps the wafer placement surface 22a in plan view of the refrigerant flow channel 32, the most upstream part 32U and the most downstream part 32L are at locations shown in FIG. 2. The width w of the refrigerant flow channel 32 at the most downstream part 32L is narrower than the width w at the most upstream part 32U, and the width w of the refrigerant flow channel 32 gradually narrows from the most upstream part 32U toward the most downstream part 32L. In other words, the flow channel cross-sectional area of the refrigerant flow channel 32 at the most downstream part 32L is less than the flow channel cross-sectional area of the refrigerant flow channel 32 at the most upstream part 32U, and the flow channel cross-sectional area gradually reduces from the most upstream part 32U toward the most downstream part 32L. Therefore, the pressure loss in the refrigerant flow channel 32 at the most downstream part 32L is larger than the pressure loss at the most upstream part 320, and the pressure loss gradually increases from the most upstream part 32U toward the most downstream part 32L. In the present embodiment, the height (the length from the bottom surface to the ceiling surface) of the refrigerant flow channel 32 is uniform. The flow channel cross-sectional area at the most downstream part 32L is preferably 60% to 90% of the flow channel cross-sectional area at the most upstream part 32U.

When the relationship between the location in the refrigerant flow channel 32 and the flow channel cross-sectional area is represented by a graph, the flow channel cross-sectional area may continuously reduce or reduce in a stepwise manner from the most upstream part 32U toward the most downstream part 32L, and preferably continuously reduces. The case where the flow channel cross-sectional area continuously reduces from the most upstream part 32U toward the most downstream part 32L may be, for example, a case where the flow channel cross-sectional area continuously reduces at a constant gradient (slope), a case where the flow channel cross-sectional area reduces while drawing a downward-convex curve, or a case where the flow channel cross-sectional area reduces while drawing an upward-convex curve.

The metal bonding layer 40 bonds the bottom surface of the ceramic base 20 with the top surface of the cooling base 30. The metal bonding layer 40 may be, for example, a layer made of solder or a brazing metal material. The metal bonding layer 40 is formed by, for example, TCB (thermal compression bonding). TCB is a known method of sandwiching a metal bonding material between two members to be bonded and bonding the two members in a state of being heated to a temperature lower than or equal to a solidus temperature of the metal bonding material.

The side surface of the outer peripheral part 24 of the ceramic base 20, the outer periphery of the metal bonding layer 40, and the side surface of the cooling base 30 are coated with an electrically insulating film 42. Examples of the electrically insulating film 42 include a sprayed film made of alumina, yttria, or the like.

The thus configured wafer placement table 10 is attached to the mounting plate 96 inside the chamber 94 by using a clamp member 70. The clamp member 70 is an annular member with a substantially inverted L-shaped cross section and has an inner peripheral step surface 70a. The wafer placement table 10 and the mounting plate 96 are united by the clamp member 70. In a state where the inner peripheral step surface 70a of the clamp member 70 is placed on the flange 34 of the cooling base 30 of the wafer placement table 10, bolts 72 are inserted from the top surface of the clamp member 70 and screwed to threaded holes provided on the top surface of the mounting plate 96. The bolts 72 are inserted at multiple locations (for example, eight locations or 12 locations) provided at equal intervals along the circumferential direction of the clamp member 70. The clamp member 70 and the bolts 72 may be made of an electrically insulating material or may be made of an electrically conductive material (metal or the like).

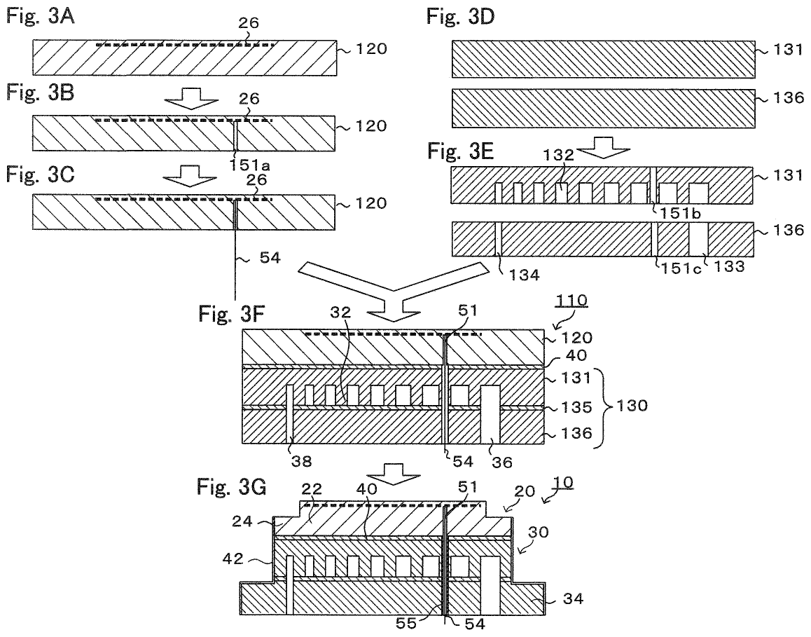

Next, an example of manufacturing of the wafer placement table 10 will be described with reference to FIGS. 3A to 3G. FIGS. 3A to 3G are manufacturing process charts of the wafer placement table 10. Initially, a disk-shaped ceramic sintered body 120 that is the source of the ceramic base 20 is made by firing a ceramic powder molded body by hot pressing (FIG. 3A). The ceramic sintered body 120 incorporates the wafer attraction electrode 26.

Subsequently, a terminal hole upper part 151a is formed from the bottom surface of the ceramic sintered body 120 to the wafer attraction electrode 26 (FIG. 3B). Then, the power supply terminal 54 is inserted into the terminal hole upper part 151a, and the power supply terminal 54 and the wafer attraction electrode 26 are bonded (FIG. 3C).

In parallel with this, two MMC disk members 131, 136 are made (FIG. 3D). Then, holes extending through both the MMC disk members 131, 136 in the up and down direction are perforated, and a groove 132 that will be finally the refrigerant flow channel 32 is formed on the bottom surface of the upper-side MMC disk member 131 (FIG. 3E).

Specifically, a terminal hole middle part 151b is perforated in the upper-side MMC disk member 131 as a hole, and a groove 132 is formed by machining. A terminal hole lower part 151c, a refrigerant supply through-hole 133, and a refrigerant discharge through-hole 134 are perforated in the lower-side MMC disk member 136 as holes. When the ceramic sintered body 120 is made of alumina, the MMC disk members 131, 136 are preferably made of SiSiCTi or AlSiC. This is because the coefficient of thermal expansion of alumina and the coefficient of thermal expansion of SiSiCTi or AlSiC are almost the same.

The disk member made of SiSiCTi can be made by, for example, as follows. Initially, a powder mixture is made by mixing silicon carbide, metal Si and metal Ti. After that, a disk-shaped molded body is made by uniaxial pressing of the obtained powder mixture, and the molded body is sintered by hot pressing in an inert atmosphere, with the result that the disk member made of SiSiCTi is obtained.

Subsequently, a metal bonding material is disposed between the bottom surface of the upper-side MMC disk member 131 and the top surface of the lower-side MMC disk member 136, and another metal bonding material is disposed on the top surface of the upper-side MMC disk member 131. Through-holes are provided in advance in each of the metal bonding materials at locations facing the holes. The power supply terminal 54 of the ceramic sintered body 120 is inserted into the terminal hole middle part 151b and the terminal hole lower part 151c, and the ceramic sintered body 120 is placed on the metal bonding material disposed on the top surface of the MMC disk member 131. Thus, a laminated body in which the lower-side MMC disk member 136, the metal bonding material, the upper-side MMC disk member 131, the metal bonding material, and the ceramic sintered body 120 are laminated in this order from the bottom is obtained. By pressurizing the laminated body while heating the laminated body (TCB), a bonded body 110 is obtained (FIG. 3F). The bonded body 110 is configured such that the ceramic sintered body 120 is bonded via the metal bonding layer 40 to the top surface of the MMC block 130 that is the source of the cooling base 30. The MMC block 130 is the one in which the upper-side MMC disk member 131 and the lower-side MMC disk member 136 are bonded via a metal bonding layer 135. The MMC block 130 has the refrigerant flow channel 32, the refrigerant supply passage 36, the refrigerant discharge passage 38, and the terminal hole 51. The terminal hole 51 is a hole made up of the continuous terminal hole upper part 151a, terminal hole middle part 151b, and terminal hole lower part 151c.

TCB is performed, for example, as follows. In other words, the laminated body is pressurized at a temperature lower than or equal to a solidus temperature of the metal bonding material (for example, higher than or equal to a temperature obtained by subtracting 20° C. from the solidus temperature and lower than or equal to the solidus temperature) to perform bonding, after that the temperature is returned to a room temperature. Thus, the metal bonding material becomes the metal bonding layer. An Al—Mg bonding material or an Al—Si—Mg bonding material may be used as the metal bonding material at this time. When, for example, TCB is performed by using an Al—Si—Mg bonding material, the laminated body is pressurized in a state of being heated under vacuum atmosphere. The metal bonding material with a thickness of about 100 μm is preferable.

Subsequently, the ceramic base 20 with the central part 22 and the outer peripheral part 24 is obtained by cutting the outer periphery of the ceramic sintered body 120 to form a step. The cooling base 30 with the flange 34 is obtained by cutting the outer periphery of the MMC block 130 to form a step. The electrically insulating tube 55 that allows insertion of the power supply terminal 54 is disposed in the terminal hole 51 from the bottom surface of the ceramic base 20 to the bottom surface of the cooling base 30. The side surface of the outer peripheral part 24 of the ceramic base 20, the periphery of the metal bonding layer 40, and the side surface of the cooling base 30 are subjected to thermal spraying by using ceramic powder to form the electrically insulating film 42 (FIG. 3G). Thus, the wafer placement table 10 is obtained.

The cooling base 30 of FIG. 1 has been described as a single-piece product; however, as shown in FIG. 3G, the cooling base 30 may be configured such that two members are bonded by a metal bonding layer or may be configured such that three or more members are bonded by metal bonding layers.

Next, an example of the use of the wafer placement table 10 will be described with reference to FIG. 1. The wafer placement table 10 is fixed to the mounting plate 96 in the chamber 94 by the clamp member 70 as described above. A shower head 98 that discharges process gas from a large number of gas injection holes into the chamber 94 is disposed on the ceiling surface of the chamber 94.

A focus ring 78 is placed on the FR placement surface 24a of the wafer placement table 10, and a disk-shaped wafer W is placed on the wafer placement surface 22a. The focus ring 78 has a step along the inner periphery of an upper end part so as not to interfere with the wafer W. In this state, the wafer W is attracted to the wafer placement surface 22a by applying a direct current voltage of the wafer attraction direct current power supply 52 to the wafer attraction electrode 26. Then, the inside of the chamber 94 is set to a predetermined vacuum atmosphere (or reduced-pressure atmosphere), and an RF voltage from the RF power supply 62 is applied to the cooling base 30 while process gas is being supplied from the shower head 98. As a result, plasma is generated between the wafer W and the shower head 98. Then, the wafer W is subjected to CVD deposition or etching by using the plasma. As the wafer W is subjected to a plasma process, the focus ring 78 abrades; however, the focus ring 78 is thicker than the wafer W, replacement of the focus ring 78 is performed after processing a plurality of wafers W.

When a wafer W is processed with high-power plasma, it is necessary to efficiently cool the wafer W. In the wafer placement table 10, not a resin layer with a low thermal conductivity but the metal bonding layer 40 with a high thermal conductivity is used as the bonding layer between the ceramic base 20 and the cooling base 30. Therefore, performance to dissipate heat from a wafer W (heat dissipation performance) is high. Since a difference in thermal expansion between the ceramic base 20 and the cooling base 30 is small, a trouble is less likely to occur even when stress relaxation properties of the metal bonding layer 40 are low. Furthermore, the width w of the refrigerant flow channel 32 at the most downstream part 32L of the refrigerant flow channel 32 is narrower than the width w at the most upstream part 32U of the refrigerant flow channel 32. In other words, the cross-sectional area of the refrigerant flow channel 32 at the most downstream part 32L of the refrigerant flow channel 32 is less than the cross-sectional area at the most upstream part 32U of the refrigerant flow channel 32. Therefore, the pressure loss in the refrigerant flow channel 32 at the most downstream part 32L of the refrigerant flow channel 32 is larger than the pressure loss at the most upstream part 32U of the refrigerant flow channel 32. When the wafer placement table 10 is used, refrigerant flows from the most upstream part 320 of the refrigerant flow channel 32 toward the most downstream part 32L of the refrigerant flow channel 32 while dissipating heat from a high-temperature wafer W, so the temperature of refrigerant flowing through the refrigerant flow channel 32 at the most downstream part 32L is higher than the temperature of refrigerant flowing through the refrigerant flow channel 32 at the most upstream part 32U. On the other hand, since the pressure loss in the refrigerant flow channel 32 at the most downstream part 32L of the refrigerant flow channel 32 is larger than the pressure loss at the most upstream part 32U of the refrigerant flow channel 32, heat exchange between refrigerant and the wafer is more promoted at the most downstream part 32L than at the most upstream part 32U. Therefore, generally, it is possible to reduce the temperature difference between a location facing the most upstream part 32U of the refrigerant flow channel 32 and a location facing the most downstream part 32L of the refrigerant flow channel 32 in the wafer placement surface 22a. The flow rate of refrigerant flowing through the refrigerant flow channel 32 is preferably set to 15 L/min to 50 L/min and more preferably set to 20 L/min to 40 L/min.

In the above-described wafer placement table 10 of the present embodiment, the cross-sectional area of the refrigerant flow channel 32 at the most downstream part 32L is less than the cross-sectional area of the refrigerant flow channel 32 at the most upstream part 32U, so the soaking performance of a wafer W increases.

The cross-sectional area of the refrigerant flow channel 32 gradually reduces from the most upstream part 32U of the refrigerant flow channel 32 toward the most downstream part 32L of the refrigerant flow channel 32. Therefore, the soaking performance of a wafer W further increases.

Furthermore, the cross-sectional area of the refrigerant flow channel 32 is adjusted by the width w of the refrigerant flow channel 32. Therefore, the cross-sectional area of the refrigerant flow channel 32 is relatively easily adjusted.

Furthermore, the refrigerant flow channel 32 is formed in a zigzag shape when the cooling base 30 is viewed in plan. Therefore, the refrigerant flow channel 32 is easily routed all over the cooling base 30.

The cross-sectional area of the refrigerant flow channel at the most downstream part 32L is preferably 60% to 90% of the cross-sectional area of the refrigerant flow channel at the most upstream part 32U. When the percentage is lower than or equal to 90%, the soaking performance of a wafer W sufficiently increases. When the percentage is higher than or equal to 60%, refrigerant is able to flow at a sufficient flow rate without an excessively large pressure loss.

In addition, the cooling base 30 is made of an MMC and is bonded to the ceramic base 20 via the metal bonding layer 40. With the structure that the cooling base 30 is an MMC and the bonding layer is the metal bonding layer 40, thermal resistance from the refrigerant flow channel 32 to the wafer placement surface 22a is small, so the wafer temperature is susceptible to the influence of the temperature gradient of refrigerant. Therefore, the significance to apply the present invention is high. Since the metal bonding layer 40 has a high thermal conductivity, the metal bonding layer 40 is suitable for heat dissipation. Since a difference in thermal expansion between the ceramic base 20 and the cooling base 30 made of an MMC is able to be reduced, a trouble is less likely to occur even when the stress relaxation properties of the metal bonding layer 40 are low.

The present invention is not limited to the above-described embodiment and may be, of course, implemented in various modes within the technical scope of the present invention.

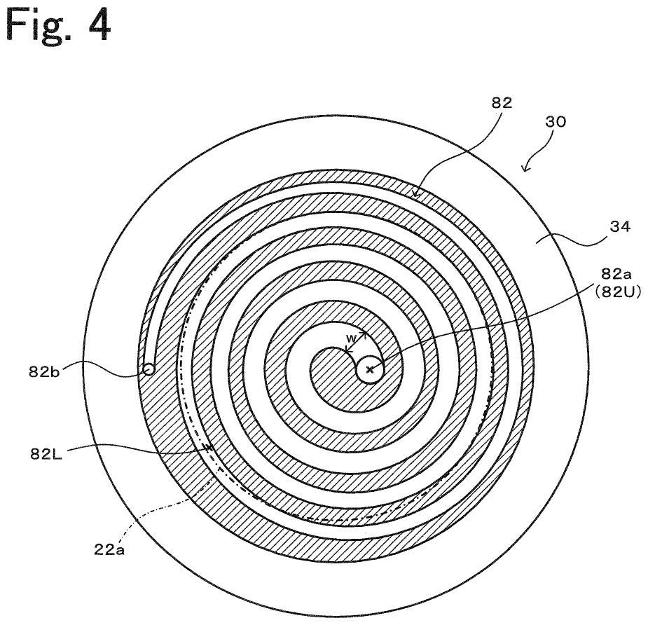

In the above-described embodiment, instead of the refrigerant flow channel 32 in a zigzag shape in plan view, a refrigerant flow channel 82 in a spiral shape in plan view may be adopted as shown in FIG. 4. The refrigerant flow channel 82 is formed in a spiral shape all over a part excluding the flange 34 of the cooling base 30 in a one-stroke pattern from an inlet 82a provided at the center to an outlet 82b provided at an outer peripheral part. In this case, when a most upstream part 82U and a most downstream part 82L are determined in an area that overlaps the wafer placement surface 22a in plan view of the refrigerant flow channel 82, the most upstream part 82U and the most downstream part 82L are at locations shown in FIG. 4. The width w (flow channel cross-sectional area) of the refrigerant flow channel 82 at the most downstream part 82L is shorter than the width w at the most upstream part 82U. The width w gradually reduces from the most upstream part 82U toward the most downstream part 82L. Alternatively, the outer peripheral part of the refrigerant flow channel 82 may be set as an inlet, and the center may be set as an outlet.

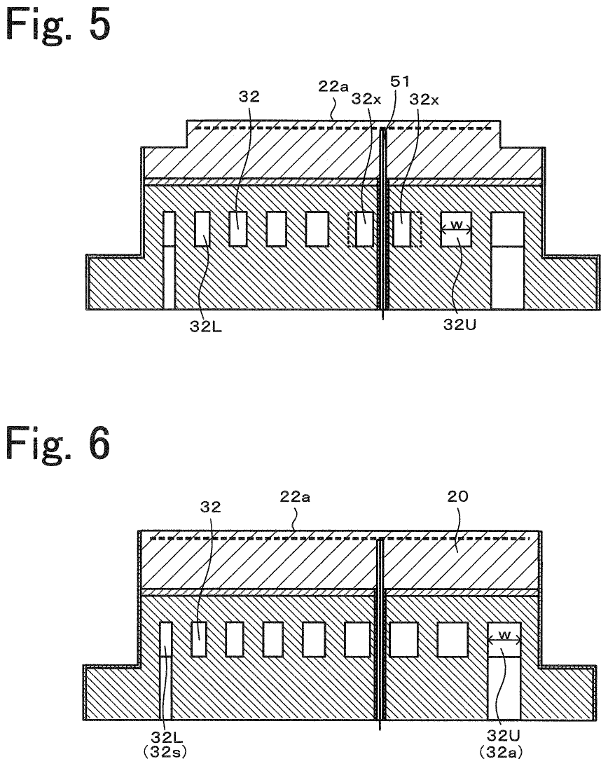

In the above-described embodiment, as shown in FIG. 5, the refrigerant flow channel 32 may have a part 32x where the width w (flow channel cross-sectional area) of the refrigerant flow channel 32 in an area around the terminal hole 51 is narrower than the width w in an area outside the area around the terminal hole 51. FIG. 5 is similar to the above-described embodiment except that the part 32x is provided in the refrigerant flow channel 32. The width w at the most downstream part 32L is narrower than the width w at the most upstream part 32U. The width w gradually narrows from the most upstream part 32U of the refrigerant flow channel 32 toward the most downstream part 32L of the refrigerant flow channel 32 except that an area around the terminal hole 51. Generally, an area around just above such the terminal hole 51 in the wafer placement surface 22a tends to be a hot spot, and, here, the width w (flow channel cross-sectional area) in an area around the terminal hole 51 is narrower than the width w (flow channel cross-sectional area) in an area outside the area around the terminal hole 51. Therefore, heat dissipation of the area around the terminal hole 51 is promoted. As a result, the soaking performance of a wafer W further increases. The flow channel cross-sectional area at the part 32x is preferably 60% to 90% of the flow channel cross-sectional area at the most upstream part 32U.

In the above-described embodiment, as shown in FIG. 6, the ceramic base 20 has the wafer placement surface 22a but the ceramic base 20 does not need to have an FR placement surface. In this case, when the most upstream part 32U and the most downstream part 32L are determined in an area that overlaps the wafer placement surface 22a in plan view of the refrigerant flow channel 32, the most upstream part 32U and the most downstream part 32L respectively coincide with the inlet 32a and the outlet 32s.

In the above-described embodiment, the cross-sectional area of the refrigerant flow channel 32 is adjusted by the width w of the refrigerant flow channel 32; however, the configuration is not limited thereto. For example, the cross-sectional area of the refrigerant flow channel 32 may be adjusted by the height (the length from the bottom surface to the ceiling surface) of the refrigerant flow channel 32. At this time, the distance from the ceiling surface of the refrigerant flow channel 32 to the wafer placement surface 22a and the width w of the refrigerant flow channel 32 are constant from the inlet 32a to the outlet 32s, and the level of the bottom surface of the refrigerant flow channel 32 is adjusted. With this configuration as well, the flow channel cross-sectional area of the refrigerant flow channel 32 at the most downstream part 32L is less than the flow channel cross-sectional area at the most upstream part 32U, and the pressure loss in the refrigerant flow channel 32 at the most downstream part 32L is larger than the pressure loss at the most upstream part 32U.

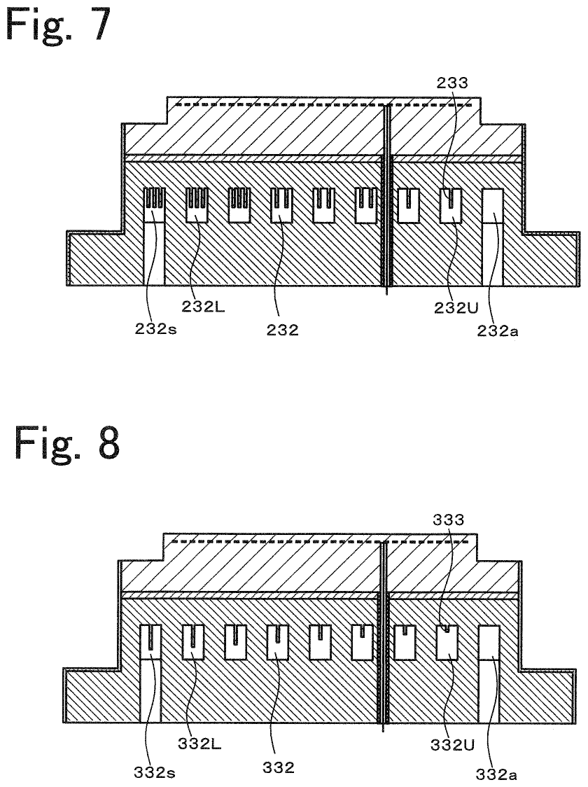

Alternatively, as shown in FIG. 7, the cross-sectional area of a refrigerant flow channel 232 may be adjusted by the number of fins 233 provided on the inner surface of the refrigerant flow channel 232. FIG. 7 is similar to the above-described embodiment except that the refrigerant flow channel 232 with the fins 233 is provided instead of the refrigerant flow channel 32. The shape of the refrigerant flow channel 232 in plan view is a zigzag shape from an inlet 232a to an outlet 232s, as in the case of FIG. 2. The width and the height (the length from the bottom surface to the ceiling surface) of the refrigerant flow channel 232 are the same through the overall flow channel; however, the number of the fins 233 at a most downstream part 232L is greater than the number of the fins 233 at a most upstream part 232U. The number of the fins 233 gradually increases from the most upstream part 232U toward the most downstream part 232L. The sectional shape of each fin 233 is the same. With this configuration as well, the cross-sectional area of the refrigerant flow channel 232 at the most downstream part 232L is less than the cross-sectional area of the refrigerant flow channel 232 at the most upstream part 232U, and the cross-sectional area is gradually reduced from the most upstream part 232U toward the most downstream part 232L. Turbulent flow tends to more easily occur at a portion where the number of the fins 233 increases, and heat exchange with a wafer W is promoted. The number of the fins 233 at the most downstream part 232L may be greater by 10% to 40% than the number of the fins 233 at the most upstream part 232U. In other words, the number of the fins 233 at the most downstream part 232L may be 110% to 140% of the number of the fins 233 at the most upstream part 232U.

Alternatively, as shown in FIG. 8, the cross-sectional area of a refrigerant flow channel 332 may be adjusted by the length of a fin 333 provided on the inner surface of the refrigerant flow channel 332. FIG. 8 is similar to the above-described embodiment except that the refrigerant flow channel 332 with the fin 333 is provided instead of the refrigerant flow channel 32. The shape of the refrigerant flow channel 332 in plan view is a zigzag shape from an inlet 332a to an outlet 332s, as in the case of FIG. 2. The width and the height (the length from the bottom surface to the ceiling surface) of the refrigerant flow channel 332 are the same through the overall channel. The number of the fins 333 is the same (here, one) through the overall channel, and the length of the fin 333 at a most downstream part 332L is longer than the length of the fin 333 at a most upstream part 332U. The length of the fin 333 gradually increases from the most upstream part 332U toward the most downstream part 332L. The thickness of each fin 333 is the same. With this configuration as well, the cross-sectional area of the refrigerant flow channel 332 at the most downstream part 332L is less than the cross-sectional area of the refrigerant flow channel 332 at the most upstream part 332U, and the cross-sectional area is gradually reduced from the most upstream part 332U toward the most downstream part 332L. Turbulent flow tends to more easily occur at a portion where the length of the fin 333 increases, and heat exchange with a wafer W is promoted. The length of the fin 333 at the most downstream part 332L may be greater by 10% to 40% than the length of the fin 333 at the most upstream part 332U. In other words, the length of the fin 333 at the most downstream part 332L may be 110% to 140% of the length of the fin 333 at the most upstream part 332U. In FIG. 7 and FIG. 8, the shape of the refrigerant flow channel 232 or the refrigerant flow channel 332 in plan view is not limited to a zigzag shape and may be, for example, a spiral shape (see FIG. 4).

In the above-described embodiment, the width w of the refrigerant flow channel 32 gradually narrows from the most upstream part 32U toward the most downstream part 32L; however, the configuration is not limited thereto. The width w may be configured in any shape between the most upstream part 32U and the most downstream part 32L as long as the width w at the most downstream part 32L is narrower than the width w at the most upstream part 32U. For example, between the most upstream part 32U and the most downstream part 32L, there may be a section in which the width w is uniform, or a section in which the width w gradually increases from the most upstream part 32U toward the most downstream part 32L, or a section in which the width w irregularly changes.

In the above-described embodiment, on the wafer placement surface 22a, a seal band may be formed along the outer periphery, a plurality of small projections may be formed all over the surface, and a wafer W may be supported by the top face of the seal band and the top faces of the small projections.

In the above-described embodiment, the wafer placement table 10 may have a plurality of holes that extend through the wafer placement table 10 in the up and down direction. Such holes include a plurality of gas holes that open at the wafer placement surface 22a and lift pin holes for allowing insertion of lift pins used to raise and lower the wafer W with respect to the wafer placement surface 22a. The plurality of gas holes is provided at adequate locations when the wafer placement surface 22a is viewed in plan. Heat transfer gas, such as He gas, is supplied to the gas holes. Generally, the gas holes are provided so as to open at locations where the seal band or the small projections are not provided on the wafer placement surface 22a on which the seal band and the small projections are provided. When heat transfer gas is supplied to the gas holes, heat transfer gas is filled into a space on the back side of the wafer W placed on the wafer placement surface 22a. The plurality of lift pin holes is provided at equal intervals along the concentric circle of the wafer placement surface 22a when the wafer placement surface 22a is viewed in plan. When the wafer placement table 10 has gas holes and lift pin holes, a part where the width w of the refrigerant flow channel 32 is narrower in an area around each hole than in an area outside the area around each hole may be provided as in the case of the part 32x of FIG. 5. With this configuration, the soaking performance of a wafer W further increases.

In the above-described embodiment, the cooling base 30 is made of an MMC; however, the configuration is not limited thereto. The cooling base 30 may be made of metal (for example, aluminum, titanium, molybdenum, tungsten, and alloys of them).

In the above-described embodiment, the ceramic base 20 and the cooling base 30 are bonded via the metal bonding layer 40; however, the configuration is not limited thereto. For example, instead of the metal bonding layer 40, a resin bonding layer may be used.

In the above-described embodiment, the wafer attraction electrode 26 is incorporated in the central part 22 of the ceramic base 20. Instead of or in addition to this, an RF electrode for generating plasma may be incorporated, and a heater electrode (resistance heating element) may be incorporated. A focus ring (FR) attraction electrode may be incorporated in the outer peripheral part 24 of the ceramic base 20, and an RE electrode or a heater electrode may be incorporated.

In the above-described embodiment, the ceramic sintered body 120 of FIG. 3A is made by firing a ceramic powder molded body by hot pressing. The molded body at that time may be made by laminating a plurality of molded tapes, or may be made by mold casting, or may be made by compacting ceramic powder.

The present application claims priority from Japanese Patent Application No. 2021-183241, filed on Nov. 10, 2021, the entire contents of which are incorporated herein by reference.

What is claimed is:

1. A wafer placement table comprising:
a ceramic base having a wafer placement surface on its top surface where a wafer is able to be placed and incorporating an electrode;
a cooling base having a refrigerant flow channel; and
a bonding layer that bonds the ceramic base with the cooling base, wherein
in an area that overlaps the wafer placement surface in plan view of the refrigerant flow channel, a cross-sectional area of the refrigerant flow channel at a most downstream part of the refrigerant flow channel is less than the cross-sectional area at a most upstream part of the refrigerant flow channel.

2. The wafer placement table according to claim 1,
wherein a cross-sectional area of the refrigerant flow channel reduces from the most upstream part of the refrigerant flow channel toward the most downstream part of the refrigerant flow channel.

3. The wafer placement table according to claim 1,
wherein a cross-sectional area of the refrigerant flow channel is adjusted by at least one of fins provided in the refrigerant flow channel, the thickness of each fin, or the length of each fin.

4. The wafer placement table according to claim 1,
Wherein a cross-sectional area of the refrigerant flow channel at the most downstream part is 60% to 90% of a cross-sectional area of the refrigerant flow channel at the most upstream part.

5. The wafer placement table according to claim 1,
wherein the cooling base is made of a metal matrix composite material, and
the bonding layer is a metal bonding layer.

6. The wafer placement table according to claim 1, further comprising
a hole extending through the cooling base in an up and down direction, wherein
a cross-sectional area of the refrigerant flow channel in an area around the hole is less than a cross-sectional area of the refrigerant flow channel in an area outside the area around the hole.
